(19) United States
(12) Patent Application Publication
(10) Pub. No.: US 2025/0112129 A1
(43) Pub. Date: Apr. 3, 2025

(54) SEMICONDUCTOR MODULE

(71) Applicant: FUJI ELECTRIC CO., LTD., Kawasaki-shi (JP)

(72) Inventors: Naoyuki KANAI, Matsumoto-city (JP); Hitoshi NAKATA, Matsumoto-city (JP)

(73) Assignee: FUJI ELECTRIC CO., LTD., Kawasaki-shi (JP)

(21) Appl. No.: 18/815,355

(22) Filed: Aug. 26, 2024

(30) Foreign Application Priority Data
Sep. 28, 2023 (JP) 2023-168912

(51) Int. Cl. H01L 23/495; H01L 23/29

(52) U.S. Cl. CPC H01L 23/49534; H01L 23/293; H01L 23/49551; H01L 23/49582

(57) ABSTRACT

A semiconductor module has a stacked substrate, a semiconductor device mounted to the stacked substrate, a lead frame in contact with and electrically connecting the semiconductor device and a conductive plate on the stacked substrate, and an encapsulation resin that encapsulates encapsulated members, which include the semiconductor device, the lead frame, and the stacked substrate. The lead frame is configured by a Cu layer and an Al layer, the Cu layer being provided facing the semiconductor device and the Al layer being provided facing the encapsulation resin.

### CROSS REFERENCE TO RELATED APPLICATIONS

This application is based upon and claims the benefit of priority of the prior Japanese Patent Application No. 2023-168912, filed on Sep. 28, 2023, the entire contents of which are incorporated herein by reference.

### BACKGROUND OF THE INVENTION

### 1. Field of the Invention

Embodiments of the disclosure relate to a semiconductor module.

### 2. Description of the Related Art

One known power module has a lead frame that includes a conductive plate containing copper (Cu) or a Cu alloy; the conductive plate has a first surface and a second surface opposite to each other with a semiconductor device being mounted at the first surface; the lead frame further has an aluminum (Al) film formed at least on the second surface of the conductive plate (for example, refer to Japanese Laid-Open Patent Publication No. 2012-134222).

### SUMMARY OF THE INVENTION

According to an embodiment of the present disclosure, a semiconductor module includes: a stacked substrate; a semiconductor device mounted on the stacked substrate; a lead frame in contact with and electrically connected to the semiconductor device; and an encapsulation resin encapsulating encapsulated members including the semiconductor device, the lead frame, and the stacked substrate. The lead frame has a Cu layer and an Al layer on the Cu layer, the Cu layer facing the semiconductor device and the Al layer facing the encapsulation resin.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view of a configuration of a semiconductor module according to an embodiment.

FIG. 2 is a cross-sectional view depicting a structure of a junction between a lead frame and a semiconductor chip of the semiconductor module according to the embodiment.

FIG. 3 is a cross-sectional view depicting another structure of the junction between the lead frame and the semiconductor chip of the semiconductor module according to the embodiment.

FIG. 4 is a cross-sectional view depicting another structure of the junction between the lead frame and the semiconductor chip of the semiconductor module according to the embodiment.

FIG. 5 is a cross-sectional view depicting another structure of the junction between the lead frame and the semiconductor chip of the semiconductor module according to the embodiment.

FIG. 6 is a cross-sectional view depicting another structure of the junction between the lead frame and the semiconductor chip of the semiconductor module according to the embodiment.

FIG. 7 is a cross-sectional view depicting a structure of a junction between a lead frame and a semiconductor chip of a conventional semiconductor module.

### DETAILED DESCRIPTION OF THE INVENTION

First, problems associated with the conventional techniques are discussed. In a conventional semiconductor module, thermal stress is generated between a Cu lead frame and encapsulation resin due to a difference of the coefficients of thermal linear expansion.

In light of the problems described a semiconductor module according to the present disclosure has following features. The semiconductor module has a stacked substrate to which a semiconductor device is mounted, a lead frame electrically connected to the semiconductor device, and an encapsulation resin that encapsulates encapsulated members, including the semiconductor device, the lead frame, and the stacked substrate. The lead frame has a Cu layer and an Al layer, the Cu layer facing the semiconductor device and the Al layer facing the encapsulation resin.

According to the description above, adhesion between the encapsulation resin and the lead frame may be enhanced without degradation of bonding between the lead frame and solder, power cycling capability is enhanced, and a highly reliable product may be provided.

Further, in the semiconductor module according to the present disclosure, in the disclosure above, the Al layer is 10% to 50% of a film thickness of the lead frame.

According to the description above, adhesion between the lead frame and the epoxy resin may be enhanced 65% as compared to an existing lead frame.

Further, in the semiconductor module according to the present disclosure, in the disclosure above, the Al layer has at a surface thereof, an oxide film.

According to the description above, adhesion between the lead frame and the epoxy resin may be enhanced 76% and module reliability may be further enhanced 40%, as compared to an existing lead frame.

Further, in the semiconductor module according to the present disclosure, in the disclosure above, the oxide film has a film thickness of 5 μm to 10 μm.

According to the description above, the oxide film itself becoming brittle and degradation of both adhesion and module reliability may be prevented.

Further, in the semiconductor module according to the present disclosure, in the disclosure above, the oxide film has a barrier layer of 80 nm or greater and a hole diameter of not more than 15 nm.

According to the description above, the oxide film is formed to be denser and thus, module reliability may be further enhanced.

Further, in the semiconductor module according to the present disclosure, in the disclosure above, in the lead frame, a bent portion thereof facing the encapsulation resin is covered by the Al layer while an end of the lead frame is exposed.

Further, in the semiconductor module according to the present disclosure, in the disclosure above, the Al layer covers 30% to 80% of the lead frame including the bent portion facing the encapsulation resin.

According to the description above, module reliability may be enhanced as compared to an instance in which the Al layer is provided at the entire surface of the lead frame.

Further, in the semiconductor module according to the present disclosure, in the disclosure above, the encapsulation resin is an epoxy resin.

Here, problems of the conventional semiconductor module are discussed. The conventional semiconductor module includes a semiconductor chip, a stacked substrate, a case, a heat dissipating base, and a lead frame. The semiconductor chip is a power semiconductor chip such as a metal-oxide-semiconductor field effect transistor (MOSFET), an insulated gate bipolar transistor (IGBT), or a diode and is bonded on the stacked substrate by a bonding layer such as solder. The stacked substrate refers to an insulated substrate such as a ceramic substrate having, at a front surface thereof, a first conductive plate containing, for example, copper and at a back surface, a second conductive plate containing, for example, copper. The stacked substrate is bonded to a heat dissipating base by a bonding layer such as solder. Further, in an instance of a MOSFET, a source electrode pad is formed as a power terminal electrode pad (current supply terminal) at a surface of the semiconductor chip. Further, a conductive connecting member such as a lead frame or a metal wire is disposed as a lead terminal from the power terminal electrode pad. A case is mounted to the semiconductor module and a cover through which metal terminals penetrate and protrude externally is attached. The case is filled with an encapsulation resin that insulates and protects the stacked substrate and the semiconductor chip on the substrate.

FIG. 7 is a cross-sectional view depicting a structure of a junction between a lead frame and the semiconductor chip of the conventional semiconductor module. In an instance in which the conductive connecting member is a lead frame 110, the lead frame 110 is bonded to a semiconductor chip 101 by a bonding layer such as a solder 124 and is encapsulated by a encapsulation resin 108.

In this instance, due to the difference of the coefficients of thermal linear expansion of the lead frame 110, which contains copper, and the encapsulation resin 108, thermal stress is generated between the lead frame 110 and the encapsulation resin 108, whereby peeling of the encapsulation resin 108 from the lead frame 110 occurs. In particular, adhesion between the solder 124 and the encapsulation resin 108 is weak and thus, a problem arises in that, with the solder 124 beneath the lead frame 110 as an origin, peeling of the encapsulation resin 108 from the lead frame 110 occurs at a resin peeling portion 132.

Furthermore, peeling of the encapsulation resin 108 from the lead frame 110 further occurs at a bent portion of a front side (side facing the encapsulation resin) of the lead frame 110. Further, the lead frame 110 with the bent portion, expands and contracts due to heat cycling and is particularly subject to bending stress at junctions with an electrode and the like. Thus, when the encapsulation resin 108 peels from the lead frame 110 that is fixed by the encapsulation resin 108, the lead frame 110 may be easily moved due to thermal stress and at a bonding layer, such as the solder 124, which is subject to tensile stress from the lead frame 110, cracks and the like easily occur (bonding between the lead frame and the solder degrades). In other words, a problem arises in that, as indicated by deformation directions 135 in FIG. 7, in addition to a planar direction, the lead frame 110 is deformed vertically and thus, as the number of power cycles advances, the solder 124 beneath the lead frame 110 is subjected to stress, a crack 133 is generated in the solder 124, the power terminal electrode pad beneath the lead frame 110 is subjected to stress, gate destruction 134 occurs, and the semiconductor chip 101 is destroyed, whereby a semiconductor module 150 thereof has a short lifetime.

Embodiments of a semiconductor module according to the present disclosure are described in detail with reference to the accompanying drawings. The present disclosure is not limited by the embodiments described below.

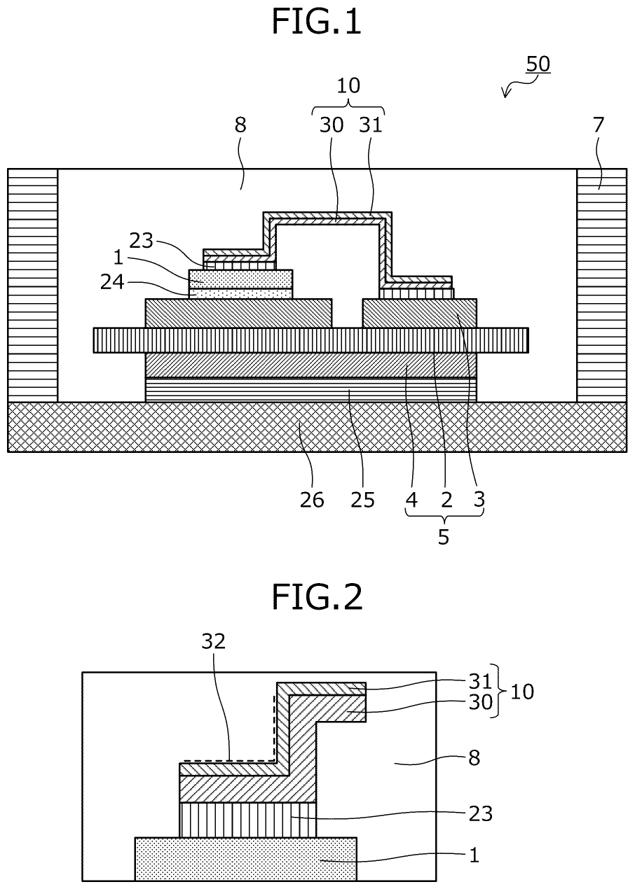

A semiconductor module according to an embodiment solving the problems above is described. FIG. 1 is a cross-sectional view of a configuration of a semiconductor module according to the embodiment. In a semiconductor module 50, a first conductive plate 3 that contains copper is provided at a front surface of an insulated substrate 2 and a second conductive plate 4 that contains copper is provided at a back surface of the insulated substrate 2, whereby a stacked substrate 5 is formed. Multiple semiconductor chips 1 are mounted at a front surface of the first conductive plate 3 of the stacked substrate 5, via a second bonding layer 24 containing solder or a sintered material. The first conductive plate 3 is formed by a predetermined circuit pattern at a front surface (first main surface) of the insulated substrate 2. The second conductive plate 4 of a back surface of the stacked substrate 5 is bonded to a front surface of a heat dissipating base 26 by a third bonding layer 25 containing solder or a sintered material. The second conductive plate 4 may be a metal foil formed in an entire area of the back surface of the insulated substrate 2.

A metal terminal (not depicted) for external output of signals is bonded inside a case 7. Further, a lead frame 10, which is a conductive connector, is provided at front surfaces (for example, a source electrode pad) of the semiconductor chips 1, via a first bonding layer 23 containing solder or a sintered material. Further, the case 7 is filled with an encapsulation resin 8. The configuration of the semiconductor module 50 depicted is one example and the present disclosure is not limited to this configuration. For example, a module structure free of the case 7 is possible.

Each of the semiconductor chips 1 is a power chip such as a MOSFET, an IGBT, or a Schottky barrier diode (SBD) and a device may be used in which Si, SiC, or GaN is used as a semiconductor substrate. In particular, the present disclosure is effective with respect to a GaN chip or a SiC chip with large power and a high Young's modulus. The number of the semiconductor chips 1 mounted may be one or more.

The stacked substrate 5 may be configured by the insulated substrate 2, the first conductive plate 3 formed in a predetermined shape at one main surface of the insulated substrate 2, and the second conductive plate 4 formed at the other main surface of the insulated substrate 2. A material with excellent electrical insulation and thermal conductivity may be used as the insulated substrate 2. For example, Al₂O₃, AlN, SiN, and the like may be used as a material of the insulated substrate 2. In particular, in high-voltage applications, a material with both electrical insulation and thermal conductivity properties is preferable and while AlN or SiN may be used, the material is not limited hereto. Cu (copper), which has excellent processability or a Cu alloy may be used as the first conductive plate 3 and the second conductive plate 4. Here, the Cu alloy is an alloy containing at least 80% Cu. Among such conductive plates containing Cu or a Cu alloy, a conductive plate apart from (not in contact with) the semiconductor chips 1 may refer to a back-surface copper foil or a back-surface conductive plate. As a method of disposing the conductive plates on the insulated substrate 2, a direct copper bonding method or active metal brazing may be given as examples. Further, nickel (Ni) plating or the like may be implemented at a conductive substrate surface and a Ni or a Ni alloy layer may be formed.

The heat dissipating base 26 is, for example, a heat sink having a substantially rectangular shape in a plan view and formed with a metal having excellent thermal conductivity such as Cu or Al, the heat dissipating base 26 is also referred to as a metal substrate. The surface of the heat dissipating base 26 may be covered by a Ni film or a Ni alloy film, which have an anticorrosion effect. The back surface of the heat dissipating base 26 may be bonded to a cooling base (not depicted). The heat dissipating base 26 conducts heat generated by the semiconductor chips 1 and transmitted via the stacked substrate 5, to heat dissipating fins. The heat dissipating fins include multiple heat dissipating fins and dissipate the heat conducted by the heat dissipating base 26. The heat dissipating base 26 itself may be a cooling apparatus such as heat dissipating fins.

The first bonding layer 23, the second bonding layer 24, the third bonding layer 25 may be formed using a lead-free solder. While not limited hereto, for example, a Sn—Sb type, a Sn—Cu type, a Sn—Ag type, a Sn—Sb—Ag type or the like may be used. Further, each bonding layer may be formed using a connecting material (bonding material containing silver nanoparticles) for a sintered material containing microscopic metal particles such as silver nanoparticles. The bonding layers may contain the same materials or materials different from one another and/or may have the same or composition or compositions different from one another.

The lead frame 10 is conductive wiring that electrically connects the first conductive plate 3 of the stacked substrate 5, output terminals, etc., from an upper electrode of the semiconductor chips 1 via the first bonding layer 23 (junction) such as a solder. The lead frame 10 has a plate-like shape; and has junctions with the upper electrode, the output terminals, etc; rising portions extending upwardly from the junctions; a wiring portion connecting the rising portions; and bent portions from the junctions to the rising portions and bent portions from the rising portions to the wiring portion. Preferably, a plate thickness may be in a range of 0.2 mm to 1.0 mm. In the embodiment, a surface metal layer is formed at a copper (Cu) layer facing the encapsulation resin 8. Preferably, the surface metal layer may be a metal capable of producing a stable oxide film layer and having a small electrical resistance. In particular, the surface metal layer contains aluminum (AI), titanium (Ti), magnesium (Mg). With consideration of electrical resistance and the like, preferably, the surface metal layer may be Al. Another metal may be contained at a rate of less than 10%. Further, other than Cu, a Cu material of the Cu layer may be Cu containing unavoidable impurities or a Cu alloy containing at least 80% by mass of Cu. The surface metal layer has excellent adhesion with epoxy resin and thus, the surface metal layer is provided facing the encapsulation resin 8, whereby adhesion with the encapsulation resin 8 may be enhanced without degradation of the adhesion with the first bonding layer 23. As a result, power cycling capability is enhanced and the lifetime of the semiconductor module 50 may be improved.

FIG. 2 is a cross-sectional view depicting the structure of the junction between the lead frame and one of the semiconductor chips of the semiconductor module according to the embodiment. FIG. 2 depicts an instance in which the surface metal layer is constituted by an Al layer 31 and the lead frame 10 is a clad material made by bonding Cu (copper) and aluminum (Al) together. The lead frame 10 is configured by a Cu layer 30 and the Al layer 31, the Cu layer 30 being provided facing the semiconductor chips 1 (the first bonding layer 23) and the Al layer 31 being provided facing the encapsulation resin 8. As a result, adhesion between the encapsulation resin 8 and the lead frame 10 may be enhanced and a highly reliable product may be provided without degradation of the bonding between the lead frame 10 and the first bonding layer 23. Further, in the lead frame 10, Al plating may be provided at one surface of the Cu instead of the clad material. The lead frame 10 on the first conductive plate 3 of the stacked substrate 5 may also contain a clad material made by bonding Cu (copper) and aluminum (Al) together similar to FIG. 2. However, above the first conductive plate 3, a small amount of heat is generated by the semiconductor chips 1 and thus, this is not always necessary.

Here, compared to Cu, Al has a more intricate natural oxide film and it is presumed that high adhesion is obtained due to OH groups of the Al oxide film surface hydrogen-bonding with polar groups such as OH groups, NH groups, carbonyl groups of the epoxy resin.

Further, while details are described below in tenth to twelfth examples, preferably, the Al layer 31 may cover bent portions of a front side of the lead frame 10. At a back side of the lead frame 10, while adhesion between the Cu layer 30 and the encapsulation resin 8 is a same as the adhesion in an existing lead frame, adhesion between the Al layer 31 and the encapsulation resin 8 is high and thus, progression of peeling at a resin peeling portion 32 is slow and deformation during thermal stress may be further suppressed. The Al layer 31 may be further formed at the back side of the lead frame 10. However, Al does not bond well with the first bonding layer 23 of the bonding material, which contains solder, silver nanoparticles, etc. and thus, preferably, the bonding surface may be the Cu layer 30. When the first bonding layer 23 is formed so as to wrap around side surfaces of the Cu layer 30 of the lead frame 1, adhesion between the first bonding layer 23 and the lead frame 10 is enhanced and thus, preferable.

Further, while details are described below in first to fifth examples, Al has a larger coefficient of linear expansion than is the coefficient of expansion of Cu and thus, from the perspective of thermal stress, it is better for the Al layer 31 to be thin and preferably, a ratio of the Al layer 31 to the Cu layer 30 may be in a range of 10% to 50%.

Further, Al forms a stable oxide film by a surface treatment, and adhesion between Al and the encapsulation resin 8 is enhanced as compared to the adhesion between Cu and the encapsulation resin 8. While details are described below in the sixth to ninth examples, as for the oxide film, the surface treatment, preferably, may be an anodizing treatment capable of selectively oxidizing only the Al. The anodizing treatment is performed, thereby forming a porous Al₂O₃ layer only above the Al, whereby an oxide film that is more robust and stable as compared to a natural oxide film is formed. Further, preferably, a thickness of the oxide film may be in a range of 5 μm to 20 μm.

In the anodizing treatment, for example, the porous Al₂O₃ layer is generated at the Al surface in a sulfuric acid electrolyte solution (sulfuric acid anodizing treatment) or in an oxalic acid electrolyte solution (oxalic acid anodizing treatment) by an electrochemical method using Al as an anode. The oxalic acid anodizing treatment enables a thicker barrier layer (thicker porous barrier layer having a plurality of pores) and smaller opening size, thereby enabling formation of a denser oxide film and thus, is more preferable. In this instance, the barrier layer is 80 nm or greater and the opening size (pore diameter) is not more than 15 nm. Here, the oxide film formed by the anodizing treatment is constituted by the barrier layer nearest the surface and the porous layer on the barrier layer, where the opening size is a diameter of holes of the porous layer.

A lower end of the case 7, which contains a resin, is adhered to a peripheral edge of the heat dissipating base 26. The case 7 has a substantially rectangular tube shape and surrounds a periphery of the front surface of the heat dissipating base 26. A box-shaped recess is formed, the recess having the front surface of the heat dissipating base 26 as a bottom, and an inner wall of the case 7 orthogonal to the front surface of the heat dissipating base 26 as sidewalls. The stacked substrate 5 and the semiconductor chips 1 connected by wiring members of the lead frame 10, etc., the wiring members, and components are housed within the recess. A material of the case 7 may be, for example, a thermosetting resin such as a phenol formaldehyde resin, or a thermoplastic resin such as polybutylene terephthalate (PBT), polyphenylene sulfide (PPS), etc. The semiconductor chips 1, the stacked substrate 5, etc. may be molded with the encapsulation resin 8 to form the semiconductor module 50 without the case 7.

The encapsulation resin 8 is used for an encapsulation resin layer that encapsulates the encapsulated members; the encapsulation resin 8 is provided in contact with the encapsulated members and mainly covers (coats) outer peripheries of the semiconductor chips 1, the stacked substrate 5, the lead frame 10, etc. The encapsulation resin 8 may be composed of a thermosetting resin composition and preferably, may be composed of a thermosetting resin composition having a high heat resistance. The thermosetting resin composition contains a thermosetting resin main agent and may optionally contain an inorganic filler, a curing agent, a curing accelerator, and necessary additives. While the thermosetting resin composition constituting the encapsulation resin 8 may or may not contain a fluorine-based silane coupling agent, it is preferable for the thermosetting resin composition to not contain a fluorine-based silane coupling agent. A reason for this is that a glass transition temperature (Tg) of the encapsulation resin 8 may be lowered.

The thermosetting resin main agent is not particularly limited and examples include an epoxy resin, a phenol formaldehyde resin, a maleimide resin, etc. Among these, an epoxy resin having at least two epoxy groups in one molecule has high dimensional stability, water resistance, chemical resistance, and electrical insulation and thus, is preferable. Preferably, in particular, aliphatic epoxy resin, alicyclic epoxy resin, or a mixture thereof may be used.

The thermosetting resin composition according to the present embodiment may contain, as an optional component, an inorganic filler (filler). While not limited hereto, the inorganic filler may be a metal oxide or a metal nitride, such as, for example, a fused silica (fused silicon dioxide), silica (silicon dioxide), alumina (aluminum oxide), aluminum hydroxide, titania (titanium oxide), zirconia (zirconium oxide), aluminum nitride, talc, clay, mica, glass fiber, or the like. Thermal conductivity of the cured product may be increased, and the coefficient of thermal expansion may be reduced by these inorganic fillers. Further, while these inorganic fillers may be used individually, two or more may combined and used. Further, these inorganic fillers may be a micro filler, a nanofiller, or a mixture of two or more inorganic fillers of different types and/or particle sizes may be used.

The thermosetting resin composition may contain, as an optional component, a curing agent in addition to the thermosetting resin main agent or in addition to the thermosetting resin main agent and the inorganic filler. There are no particular limitations for the curing agent provided that the curing agent reacts with and cures the thermosetting resin main agent, preferably, the epoxy resin main agent; however, use of an acid anhydride curing agent is preferable. The acid anhydride curing agent, for example, may be an aromatic anhydride, such as a phthalic anhydride, pyromellitic dianhydride, trimellitic anhydride, etc. Alternatively, a cyclic aliphatic anhydride, such as tetrahydrophthalic anhydride, methyltetrahydrophthalic anhydride, hexahydrophthalic anhydride, methylhexahydrophthalic anhydride, methyl nadic anhydride, etc., or an aliphatic anhydride, particularly, succinic anhydride, polyadipic anhydride, polysebacic anhydride, polyazelaic anhydride, etc. may be used. When a bisphenol type A epoxy resin alone or mixture of a bisphenol type A epoxy resin and the epoxy resin with high heat resistance described as an example above is used as the thermosetting resin main agent, it may be better not to use a curing agent because heat resistance is enhanced.

A curing accelerator may be further added as an optional component to the thermosetting resin composition. As a curing accelerator, imidazole or a derivative thereof, a tertiary amine, a borate ester, a Lewis acid, an organometallic compound, an organic acid metal salt, etc. may be suitably combined.

The thermosetting resin composition may further contain optional additives to an extent that characteristics of the thermosetting resin composition are not adversely affected. As an additive, for example, without limitation hereto, flame retardants, pigments for coloring the resin, plasticizers and silicone elastomers for enhancing resistance against cracking, etc. may be used. These optional components and the amounts thereof added may be determined according to specifications necessary for the semiconductor device and/or the encapsulating material, by one skilled in the art.

Next, a method of manufacturing the semiconductor module according to the embodiment is described. First, the heat dissipating base 26 and the stacked substrate 5 are bonded by the third bonding layer 25; and the stacked substrate 5 and the semiconductor chips 1 are bonded by the second bonding layer 24.

Subsequently, the case 7 is attached to the heat dissipating base 26 and thereafter, bonding of the lead frame 10 is performed. Next, the thermosetting resin composition constituting the encapsulation resin 8 is injected into the case 7 and heat cured. Next, the case 7 is filled with the encapsulation resin 8 and the encapsulation resin 8 is precured at a temperature of 100 degrees C. to 120 degrees C. for 10 minutes to 120 minutes and then, is cured at a temperature of about 175 degrees C. to 185 degrees C. for 1 hour to 2 hours.

As described, according to the semiconductor module of the embodiment, the lead frame is configured by the Cu layer and the Al layer, the Cu layer being provided facing the semiconductor chips and the Al layer being provided facing the encapsulation resin. As a result, adhesion between the encapsulation resin and the lead frame may be enhanced without degradation of the bonding between the lead frame and the solder, the power cycling capability may be enhanced, and a highly reliable product may be provided.

Here, examples of the present disclosure are given and the present disclosure is described in further detail. Nonetheless, the present disclosure is not limited to the following examples. Table 1 shows examples in which a rate (thickness of the Al layer 31/(thickness of the Cu layer 30+thickness of the Al layer 31)) of a thickness of the Al layer 31 (the surface metal layer) with respect to a plate thickness of the lead frame 10 is varied. Table 2 shows examples in which the surface treatment of the Al layer 31 is changed. Table 3 shows examples in which the position of the Al layer 31 on the Cu layer 30 is changed.

TABLE 1

| | | | | | | FIRST |
|---|---|---|---|---|---|---|
| | | SECOND | | FOURTH | | COMPARISON |
| | FIRST EXAMPLE | EXAMPLE | THIRD EXAMPLE | EXAMPLE | FIFTH EXAMPLE | EXAMPLE |
| LEAD FRAME | Cu(0.45 mm)/ | Cu(0.4 mm)/ | Cu(0.3 mm)/ | Cu(0.25 mm)/ | Cu(0.2 mm)/ | Cu |
| (t = 0.5 mm) | Al(0.05 mm) | Al(0.1 mm) | Al(0.2 mm) | Al(0.25 mm) | Al(0.3 mm) | |
| RATE OF THICKNESS | 10□ | 20□ | 40□ | 50□ | 60□ | |
| OF SURFACE METAL | | | | | | |
| LAYER | | | | | | |
| ADHESION: PULLING | 1.65(28 MPa) | 1.65(28 MPa) | 1.65(28 MPa) | 1.65(28 MPa) | 1.65(28 MPa) | 1(17 MPa) |
| TEST | | | | | | |
| POWER CYCLING | 1.3 | 1.3 | 1.3 | 1.2 | 1.05 | 1 |
| EVALUATION (FIRST | (65 kcycles) | (65 kcycles) | (65 kcycles) | (60 kcycles) | (52.5 kcycles) | (50 kcycles) |
| COMPARISON EXAMPLE | | | | | | |
| ASSUMED TO BE 1) | | | | | | |

In Table 1, the first to fifth examples are examples in which a total thickness t of the lead frame 10 is assumed to be 0.5 mm, the Al layer 31 is provided, and the rate of the Al layer 31 (the surface metal layer) with respect to the plate thickness of the lead frame 10 is varied; a first comparison example is an example of an existing configuration in which the plate thickness t of the lead frame 10 is assumed to be 0.5 mm and the Al layer 31 is omitted. In the first to fifth examples, a configuration of the lead frame 10 is a same as a configuration depicted in FIG. 2 while in the first comparison example, a configuration of the lead frame 110 is a same as a configuration depicted in FIG. 7. Adhesion is evaluated by a pulling test and module reliability is evaluated by a power cycling test. For each of the examples, evaluation values and rates relative to the first comparison example assumed as “1” are shown.

From the first to fifth examples in Table 1, adhesion to the epoxy resin could be enhanced 65% as compared to the first comparison example by making the Al layer 31 10% to 50% of the plate thickness of the lead frame 10. Further, by making the Al layer 31 10% to 40% of the plate thickness of the lead frame 10, module reliability could be enhanced 30%. Thus, preferably, a rate of thickness of the Al layer 31 (the surface metal layer) with respect to the plate thickness of the lead frame 10 may be in a range of 10% to 50% and more preferably, may be in a range of 10% to 40%.

When the Al layer 31 is made 50% or thicker, module reliability decreases slightly. This is presumed to be due to the lead frame 10 being susceptible to convex deformation due to the difference of the respective coefficients of linear expansion for Cu and for Al and greater stress being applied to electrodes and junctions (the first bonding layer 23). Further, while an instance in which the plate thickness t of the lead frame 10 is 0.5 mm is depicted, results are similar for an instance in which the total thickness t of the lead frame 10 is 1 mm.

TABLE 2

| | | | | | FIRST | |
|---|---|---|---|---|---|---|
| | | SEVENTH | EIGHTH | | COMPARISON | SECOND |
| | SIXTH EXAMPLE | EXAMPLE | EXAMPLE | NINTH EXAMPLE | EXAMPLE | EXAMPLE |
| LEAD FRAME | Cu(0.4 mm)/ | Cu(0.4 mm)/ | Cu(0.4 mm)/ | Cu (0.4 mm)/ | Cu | Cu(0.4 mm)/ |
| (t = 0.5 mm) | Al(0.1 mm) | Al(0.1 mm) | Al(0.1 mm) | Al(0.1 mm) | | Al(0.1 mm) |
| OXIDE FILM | SULFURIC ACID | SULFURIC ACID | OXALIC ACID | SULFURIC ACID | — | (FOR |
| TREATMENT | ANODIZING | ANODIZING | ANODIZING | ANODIZING | | REFERENCE) |
| METHOD | TREATMENT | TREATMENT | TREATMENT | TREATMENT | | NATURAL |
| | ELECTROLYSIS | ELECTROLYSIS | ELECTROLYSIS | ELECTROLYSIS | | OXIDE |
| | TEMPERATURE | TEMPERATURE | TEMPERATURE | TEMPERATURE | | FILM□ ABOUT |
| | 20□ | 20□ | 20□ | 20□ | | 5 nm TO 30 nm □ |
| | ELECTROLYTIC | ELECTROLYTIC | ELECTROLYTIC | ELECTROLYTIC | | |
| | VOLTAGE 15 V | VOLTAGE 15 V | VOLTAGE 100 V | VOLTAGE 15 V | | |
| | ELECTROLYSIS | ELECTROLYSIS | ELECTROLYSIS | ELECTROLYSIS | | |
| | TIME 0.2 h | TIME 1 h | TIME 0.5 h | TIME 1.2 h | | |
| | OXIDE FILM | OXIDE FILM | OXIDE FILM | OXIDE FILM | | |
| | THICKNESS: | THICKNESS: | THICKNESS: | THICKNESS: | | |
| | 5 μm | 20 μm | 10 μm | 24 μm | | |
| | (BARRIER | (BARRIER | (BARRIER | (BARRIER | | |
| | LAYER: 15 nm) | LAYER: 15 nm) | LAYER: 80 nm) | LAYER: 15 nm) | | |
| | (OPENING | (OPENING | (OPENING | (OPENING | | |
| | SIZE: 40 nm) | SIZE: 40 nm) | SIZE: 15 nm) | SIZE: 40 nm) | | |
| ADHESION: | 1.76(30 MPa) | 1.76(30 MPa) | 1.76(30 MPa) | 1.3(22 MPa) | 1(17 MPa) | 1.65(28 MPa) |
| PULLING TEST | | | | | | |
| POWER CYCLING | 1.35 | 1.4 | 1.45 | 1.2 | 1 | 1.3 |
| EVALUATION | (67.5 kcycles) | (70 kcycles) | (72.5 kcycles) | (60 kcycles) | (50 kcycles) | (65 kcycles) |
| (FIRST | | | | | | |
| COMPARISON | | | | | | |
| EXAMPLE | | | | | | |
| ASSUMED TO BE 1) | | | | | | |

In Table 2, the sixth, seventh, and ninth examples are examples in which the oxide film is formed by performing a sulfuric acid anodizing treatment to the surface of the Al layer 31, and the thickness of the oxide film is varied by changing the treatment period. The eighth example is an example in which the oxide film is formed by performing the oxalic acid anodizing treatment to the surface of the Al layer 31. The first comparison example and the second example are the same as the first comparison example and the second example in Table 1. The oxide film of the second example is a natural oxide film formed by being left indoors.

From the sixth to eighth examples in Table 2, a dense oxide film may be formed by performing the anodizing treatment to the lead frame 10, adhesion to the epoxy resin may be improved 76%, and the module reliability may also be improved about 40%. Further, from the seventh and eighth examples in Table 2, the oxalic acid anodizing treatment enables formation of a denser oxide film than is the oxide film formed by the sulfuric acid anodizing treatment and thus, enables the module reliability to be further enhanced.

Further, when the thickness of the oxide film is increased to 24 μm like that in the ninth example in Table 2, the oxide film itself becomes slightly brittle as compared to the oxide films in the sixth to eighth examples in which the oxide films have a thickness in a range of 5 μm to 20 μm and it is presumed that adhesion and module reliability degrade. Thus, preferably, the thickness of the oxide film formed by the anodizing treatment may be in a range of 5 μm to 20 μm.

TABLE 3

| | | | | | | FIRST |
|---|---|---|---|---|---|---|
| | SECOND | | ELEVENTH | TWELFTH | THIRTEEN | COMPARISON |
| | EXAMPLE | TENTH EXAMPLE | EXAMPLE | EXAMPLE | EXAMPLE | EXAMPLE |
| LEAD FRAME | Cu(0.4 mm)/ | Cu(0.4 mm)/ | Cu(0.4 mm)/ | Cu(0.25 mm)/ | Cu(0.2 mm)/ | Cu |
| (t = 0.5 mm) | Al(0.1 mm) | Al(0.1 mm) | Al(0.1 mm) | Al(0.25 mm) | Al(0.3 mm) | |
| | ENTIRE | COVERS 30% | COVERS 80% | COVERS 30% | COVERS 80% | |
| | SURFACE | INCLUDING | INCLUDING | OF ONLY | OF ONLY | |
| | | BENT PORTION | BENT PORTION | BONDING | BONDING | |
| | | (END EXPOSED) | (END EXPOSED) | SURFACE | SURFACE | |
| | | | | INCLUDING | INCLUDING | |
| | | | | BENT PORTION | BENT PORTION | |
| | | | | (END EXPOSED) | (END EXPOSED) | |
| ADHESION: PULLING | 1.65(28 MPa) | 1.65(28 MPa) | 1.65(28 MPa) | 1.65(28 MPa) | 1.65(28 MPa) | 1(17 MPa) |
| TEST | | | | | | |
| POWER CYCLING | 1.3 | 1.36 | 1.36 | 1.3 | 1.3 | 1 |
| EVALUATION (FIRST | (65 kcycles) | (68 kcycles) | (68 kcycles) | (65 kcycles) | (65 kcycles) | (50 kcycles) |
| COMPARI SON | | | | | | |
| EXAMPLE ASSUMED | | | | | | |
| TO BE 1) | | | | | | |

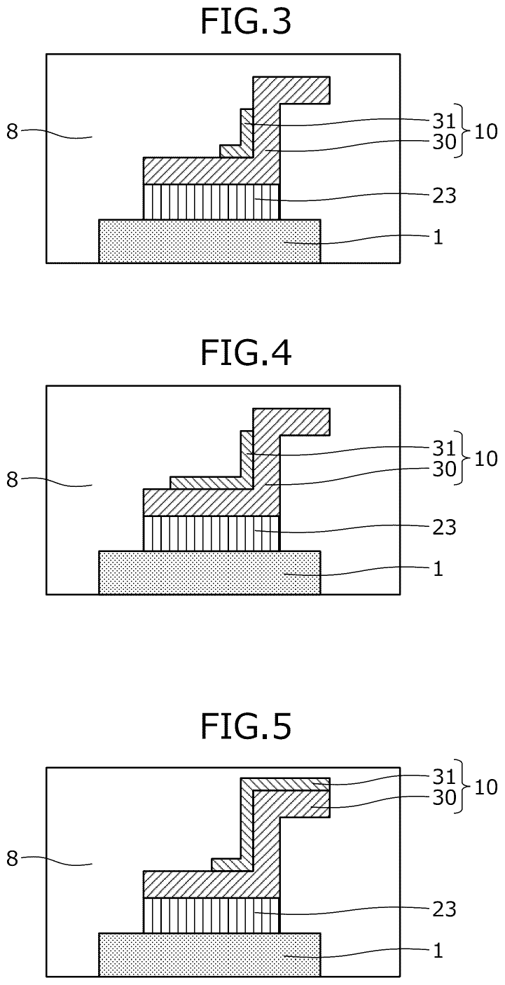

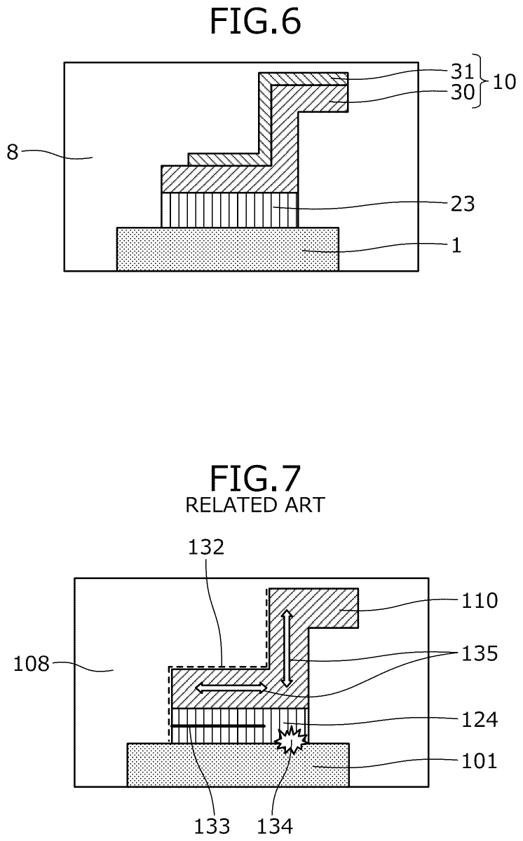

In Table 3, the tenth to thirteenth examples are examples in which the position of the Al layer 31 on the Cu layer 30 is varied. FIGS. 3, 4, 5, and 6 are cross-sectional views depicting other structures of the junction between the lead frame and the semiconductor chips of the semiconductor module according to the embodiment. FIGS. 3 to 6 correspond to the configurations of the lead frame 10 in the tenth to thirteenth examples, respectively. The first comparison example and the second example are the same as the first comparison example and the second example in Table 1. FIG. 2 corresponds to the configuration of the lead frame 10 in the second example and FIG. 7 corresponds to the configuration of the lead frame 110 in the first comparison example.

From the tenth and thirteenth examples in Table 3, module reliability is slightly better when the Al layer 31 is formed so as to cover the bent portions while leaving the ends exposed than when the Al layer 31 is formed at the entire surface of the lead frame 10 in the second example. Thus, preferably, the Al layer 31 may cover 30% to 80% of the lead frame 10 including at least the bent portions near the semiconductor chips. When the lead frame 10 has the bent portions above the semiconductor chips 1 like in FIGS. 2 to 6 and the Al layer 31 is formed at the entire surface of the lead frame 10, the module reliability improves as compared to conventionally, however, thermal stress increases at the junction between the solder and the electrode of a lower portion of a rising portion of the lead frame 10 and therefore, module reliability is better when the Al layer 31 is formed at a portion of the surface. One cause of this is thought to be deformation of the lead frame 10 due to the difference of the coefficients of linear expansion of Al and Cu.

Here, details of the pulling test and the power cycling test performed in the embodiments are described. In the pulling test, a 10 mm×10 mm Cu/Al plate imitating the junction with the lead frame was used as a substrate in the pulling test. On the substrate, an epoxy resin composition that can be used as an encapsulating material was molded having a lower surface diameter of 3.6 mm, an upper surface diameter of 3.0 mm, and a height of 3.0 mm, and a thermosetting reaction was performed at 100 degrees C. to 180 degrees C. for three hours, thereby creating a test piece of cured epoxy resin product molded on the substrate.

Measurements were performed as follows. Shear strength was measured using a force gauge (load measuring instrument: ZTA-1000N (Imada, Inc.)). Measurement conditions included a speed (strain rate) of 0.2 mm/s, pressing the cured epoxy resin product portion parallel to the adhesive surface, and assuming the strength (force) when the interface between the cured epoxy resin product and resin composite substrate peels and breaks to be the adhesive strength.

In the power cycling test, the encapsulation resin was as follows.
epoxy resin main agent: Epoxy Resin ME-276 (manufactured by Pelnox, Limited)
curing agent: Acid Anhydride MV-138 (manufactured by Pelnox, Limited)
compound ratio: added 121 parts by mass to 100 parts by mass of epoxy resin main agent
inorganic filler: fibrous silica with average particle size of 10 μm (manufactured by Nippon Electric Glass Co., Ltd.)
compound ratio: added 270 parts by mass, when total mass of epoxy resin main agent and curing agent was 100 parts by mass

In the power cycling test, the number of cycles until electrical characteristics become abnormal (20% variation from an initial value) was examined for a range of 40 degrees C. to 175 degrees C. (ΔTj=135 degrees C.) with one cycle including energized operation of 2 seconds and a pause of 9 seconds. In particular, energization was performed so that the chip temperature changed from 40 degrees C. to 175 degrees C.

In the foregoing, in the present disclosure various modifications within a range not departing from the spirit of the present disclosure are possible and in the embodiments described, for example, dimensions, doping concentrations, etc. of regions, etc. may be variously set according to necessary specifications. Further, in the embodiments described, in addition to silicon, a wide bang gap semiconductor such as silicon carbide (SiC), gallium nitride (GaN) or the like may be used as a semiconductor.

According to the disclosure described above, adhesion between the encapsulation resin and the lead frame may be enhanced without degradation of the bonding between the lead frame and solder, power cycling capability is enhanced, and a highly reliable product may be provided.

The semiconductor module according to the present disclosure achieves an effect in that adhesion between the encapsulation resin and the lead frame is enhanced without degradation of the solder bonding and a highly reliable product may be provided.

As described, the semiconductor module according to the present disclosure is useful for power semiconductor modules such as those used in power converting equipment of inverters, power source devices of various types of industrial machines, igniters of automobiles, etc.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor module, comprising:
a stacked substrate;
a semiconductor device mounted on the stacked substrate;
a lead frame in contact with and electrically connected to the semiconductor device; and
an encapsulation resin encapsulating encapsulated members including the semiconductor device, the lead frame, and the stacked substrate, wherein
the lead frame has a Cu layer and an Al layer on the Cu layer, the Cu layer facing the semiconductor device and the Al layer facing the encapsulation resin.

2. The semiconductor module according to claim 1, wherein the Al layer has a thickness that is 10% to 50% of a film thickness of the lead frame.

3. The semiconductor module according to claim 1, wherein the Al layer has at a surface thereof, an oxide film.

4. The semiconductor module according to claim 3, wherein the oxide film has a film thickness of 5 μm to 10 μm.

5. The semiconductor module according to claim 3, wherein the oxide film is a porous barrier layer of 80 nm or greater that has a plurality of pores, each pore having a diameter that is not more than 15 nm.

6. The semiconductor module according to claim 1, wherein the lead frame has a bent portion located within the encapsulation resin, and the Al layer covers the Cu layer at the bent portion while the Cu layer is exposed from the Al layer at an end of the lead frame.

7. The semiconductor module according to claim 6, wherein the Al layer covers 30% to 80% of a surface area of the lead frame including the bent portion.

8. The semiconductor module according to claim 1, wherein the encapsulation resin is an epoxy resin.
